(19) United States
(12) Patent Application Publication
(10) Pub. No.: US 2026/0162943 A1
(43) Pub. Date: Jun. 11, 2026

(54) SUBSTRATE PROCESSING APPARATUS AND SUBSTRATE PROCESSING METHOD

(71) Applicant: SEMES CO., LTD., Cheonan-si (KR)

(72) Inventors: Myoung Sub NOH, Cheonan-si (KR); Tae Hwan YOUN, Cheonan-si (KR); Wan Jae PARK, Cheonan-si (KR)

(73) Assignee: SEMES CO., LTD., Cheonan-si (KR)

(21) Appl. No.: 19/406,975

(22) Filed: Dec. 3, 2025

(30) Foreign Application Priority Data
Dec. 5, 2024 (KR) 10-2024-0179947

(51) Int. Cl. H01J 37/32; H01L 21/311

(52) U.S. Cl. CPC H01J 37/32559; H01J 37/3244; H01J 37/32568; H01J 37/32633; H10P 50/283; H01J 2237/3346

(57) ABSTRACT

A substrate processing apparatus and a substrate processing method are proposed, and the substrate processing apparatus includes a chamber having a processing space therein, a substrate support unit arranged in the processing space and for supporting a substrate, an ion blocker arranged above the substrate support unit and for dividing the processing space into an upper region where plasma is generated and a lower region, a gas supply unit for supplying a fluorine-containing gas to the upper region, an upper electrode module arranged above the ion blocker and for supplying the fluorine-containing gas to the upper region, and a high-frequency power module for applying electric power to the upper electrode module to generate the plasma in the upper region, wherein a coating layer for capturing fluorine radicals of the plasma is formed on at least a part of a surface of the upper electrode module.

### CROSS REFERENCE TO RELATED APPLICATION

The present application claims priority to Korean Patent Application No. 10-2024-0179947, filed Dec. 5, 2024, the entire contents of which are incorporated herein for all purposes by this reference.

### BACKGROUND OF THE INVENTION

### Field of the Invention

The present disclosure relates to a substrate processing apparatus and a substrate processing method and, more particularly, to a substrate processing apparatus and substrate processing method for maintaining an amount of polysilicon etched constant.

### Description of the Related Art

In semiconductor devices such as DRAM and NAND flash memory devices, recently, development is continuing to implement semiconductor devices with a large capacity and a rapidly decreasing critical dimension (CD).

In particular, as the integration of semiconductor devices is increasing and its functions become more diverse, polysilicon and silicon oxide films are widely used for patterns and insulating films of the semiconductor devices. Polysilicon may be used as a material for gate electrodes, capacitor electrodes, conductive contacts, wiring, etc., and silicon oxide films are insulating films and also used as hard masks for forming conductive patterns.

In order to use polysilicon as a material for wiring, electrodes, and the like in a semiconductor device in which both polysilicon and a silicon oxide film are formed, a pattern has to be formed. When such a pattern is formed, it is important to selectively etch the silicon oxide film relative to the polysilicon. However, when the number of process cycles increases in the course of proceeding with such an etching process, the amount of polysilicon etched increases, thereby causing a problem in that it is difficult to control the etching selectivity between the polysilicon and the silicon oxide film.

### SUMMARY OF THE INVENTION

The present disclosure is for solving a conventional problem and relates to a substrate processing apparatus and a substrate processing method for maintaining an amount of polysilicon etched constant.

The problem to be solved by the present disclosure is not limited to the problem mentioned above, and other problems not mentioned will be clearly understood by those skilled in the art from the following description.

According to one exemplary embodiment of the present disclosure, there is provided a substrate processing apparatus, including: a chamber having a processing space therein; a substrate support unit arranged in the processing space and for supporting a substrate; an ion blocker arranged above the substrate support unit and for dividing the processing space into an upper region where plasma is generated and a lower region; a gas supply unit for supplying a fluorine-containing gas to the upper region; an upper electrode module arranged above the ion blocker and for supplying the fluorine-containing gas to the upper region; and a high-frequency power module for applying electric power to the upper electrode module to generate the plasma in the upper region, wherein a coating layer for capturing fluorine radicals of the plasma is formed on at least a part of a surface of the upper electrode module.

According to one exemplary embodiment of the present disclosure, there is provided a substrate processing apparatus, including: a chamber having a processing space therein; a substrate support unit arranged in the processing space and for supporting a substrate; an ion blocker arranged above the substrate support unit and for dividing the processing space into an upper region and a lower region; a shower head arranged below the ion blocker and dividing the lower region into a first region and a second region; a gas supply unit for supplying a fluorine-containing gas to the upper region; an upper electrode module arranged above the ion blocker and for supplying the gas to the upper region; a high-frequency power module for applying electric power to the upper electrode module to generate plasma in the upper region; and a control unit for controlling the gas supply unit and the high-frequency power module, wherein the upper electrode module includes: a first electrode; a second electrode arranged below the first electrode; and a plate arranged below the second electrode, a coating layer is formed on a surface of the upper electrode module, and the coating layer includes nickel.

According to one exemplary embodiment of the present disclosure, there is provided a method of processing a substrate in a substrate processing apparatus including a chamber having a processing space therein, a substrate support unit arranged in the processing space and configured to support the substrate, an ion blocker arranged above the substrate support unit and configured to divide the processing space into an upper region and a lower region, an upper electrode module arranged above the ion blocker and configured to supply a fluorine-containing gas to the upper region and have at least a part thereof including a coating layer including nickel, a high-frequency power module configured to apply electric power to the upper electrode module to generate plasma in the upper region, the method including: a plasma forming step of forming the plasma by supplying the fluorine-containing gas to the upper region; and an etching step of supplying a hydrogen-containing gas to the lower region, mixing radicals of the plasma generated in the plasma forming step with the hydrogen-containing gas supplied to the lower region so as to form an etchant, and etching the substrate by using the generated etchant.

According to the present disclosure, by forming a nickel coating layer on an upper electrode module of the substrate processing apparatus, the amount of F radicals reaching a substrate may be maintained at a constant level.

In this way, even when the number of process cycles increases, the amount of F radicals reaching the substrate including polysilicon and a silicon oxide film remains constant, so the amount of polysilicon etched may be maintained constant. Accordingly, the etching selectivity between the polysilicon and the silicon oxide film may be controlled.

In addition, by controlling the ratio of fluorine-containing gas and hydrogen-containing gas supplied to a substrate, the etching selectivity between polysilicon and a silicon oxide film may be controlled.

However, the effects of the present disclosure are not limited to the above-mentioned effects, and another effect that is not mentioned will be clearly understood by those skilled in the art from the following drawings.

### BRIEF DESCRIPTION OF THE DRAWINGS

FIG. 1 is a view illustrating a substrate processing apparatus according to one exemplary embodiment of the present disclosure.

FIG. 2 is an enlarged view illustrating an upper electrode module according to one exemplary embodiment of the present disclosure.

FIG. 3 is an enlarged view illustrating coating layers formed in the substrate processing apparatus illustrated in FIG. 1.

FIG. 4 is a view illustrating the flow of gas in the substrate processing apparatus according to one exemplary embodiment of the present disclosure.

FIG. 5 is a flowchart illustrating a substrate processing method according to one exemplary embodiment of the present disclosure.

FIG. 6 is a graph illustrating the amounts of polysilicon etched depending on the number of process cycles according to one exemplary embodiment of the present disclosure.

FIG. 7 is a graph illustrating the amounts of polysilicon etched depending on supply ratio of fluorine-containing gas and hydrogen-containing gas according to one exemplary embodiment of the present disclosure.

### DETAILED DESCRIPTION OF THE INVENTION

Hereinafter, with reference to the attached drawings, exemplary embodiments of the present disclosure will be described in detail so that those skilled in the art to which the present disclosure pertains may easily embody the present disclosure. However, the present disclosure may be implemented in many different forms and is not limited to the exemplary embodiments described herein.

In describing the exemplary embodiments of the present disclosure, in a case where it is determined that a specific description of a related known function or configuration may unnecessarily obscure the gist of the present disclosure, the specific description will be omitted, and parts having similar functions and actions will be designated by the same reference numerals throughout the drawings.

At least some of the terms used in the present specification are defined in consideration of the functions in the embodiment of the present disclosure, and may vary depending on users, intentions of operators, customs, etc. Therefore, the terms should be interpreted on the basis of the content of the present specification as a whole.

In the present specification, the singular form also includes the plural form unless otherwise specified in the phrase. In the present specification, when it is said that a component is included, this does not mean that other components are excluded, but rather that other components may be further included, unless otherwise specifically stated.

Meanwhile, the sizes, shapes, line thicknesses, etc. of components in the drawings may be somewhat exaggerated for ease of understanding.

Hereinafter, the exemplary embodiments of the present disclosure will be described in detail with reference to the attached drawings. In describing with reference to the attached drawings, identical or corresponding components are given the same reference numerals regardless of the drawing numbers, and redundant descriptions thereof will be omitted.

A substrate according to one exemplary embodiment of the present disclosure may be a substrate including polysilicon and a silicon oxide film on a silicon substrate.

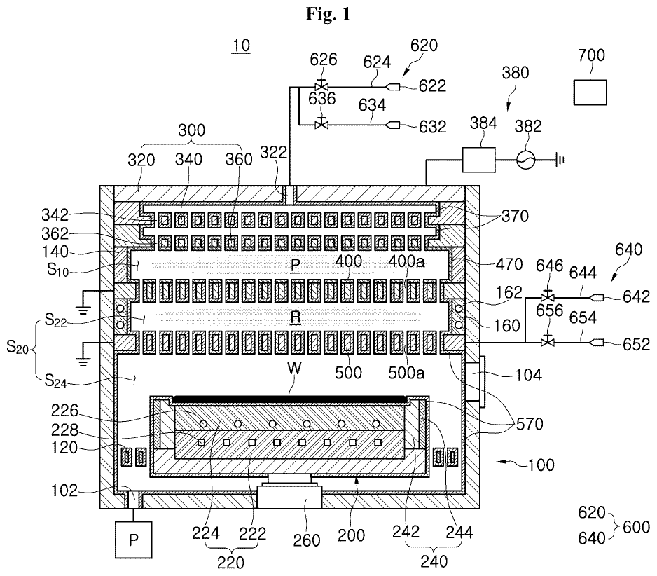

FIG. 1 is a view illustrating a substrate processing apparatus according to one exemplary embodiment of the present disclosure.

Referring to FIG. 1, the substrate processing apparatus 10 may include a chamber 100, a substrate support unit 200, an upper electrode module 300, an ion blocker 400, a shower head 500, a gas supply unit 600, and a control unit 700.

The chamber 100 has a processing space where a plasma process is performed. Such a chamber 100 may have a lower part thereof provided with an exhaust port 102. The exhaust port 102 may be connected to an exhaust line equipped with a pump P. Through the exhaust line, the exhaust port 102 may discharge not only reaction byproducts generated in the course of a plasma process but also gases remaining inside the chamber 100 to the outside of the chamber 100. In this case, the internal space of the chamber 100 may be depressurized to have a predetermined pressure.

The chamber 100 may have a side wall thereof formed with an opening 104. The opening 104 may function as a passage through which a substrate W enters and exits the interior of the chamber 100. Such an opening 104 may be configured to be opened and closed by a door assembly.

The baffle unit 120 may serve to exhaust plasma process byproducts, unreacted gases, etc. The baffle unit 120 may be installed between the inner wall of the chamber 100 and an electrostatic chuck 220. The baffle unit 120 may be provided in an annular ring shape and may have a plurality of through holes penetrating in a vertical direction. The flow of process gas may be controlled depending on the number and shape of the through holes of the baffle unit 120.

The substrate support unit 200 may be arranged in the processing space of the chamber 100. Such a substrate support unit 200 may support the substrate W by electrostatic force. However, the present exemplary embodiment is not limited thereto, and the substrate W may be supported in various means, such as mechanical clamping, vacuum, etc.

In a case of supporting the substrate W by using electrostatic force, the substrate support unit 200 may include the electrostatic chuck 220 including a base member 222 and a chucking member 224. The base member 222 supports the chucking member 224. For example, the base member 222 may be provided as an aluminum base plate made of aluminum. The chucking member 224 supports the substrate W mounted on an upper part thereof by using electrostatic force. Such a chucking member 224 may be manufactured by using ceramic as a material and provided as a ceramic plate or a ceramic puck, and may be combined with the base member 222 so as to be fixed on the base member 222. Although not shown, between the base member 222 and the chucking member 224 formed thereon, a bonding layer may be formed.

For maintaining the substrate W at a process temperature in the course of proceeding with the process, a heating member 226 and a cooling member 228 may be provided inside the base member 222 or inside the chucking member 224. The heating member 226 may be provided as a heating wire. The cooling member 228 may be provided as a cooling line through which a refrigerant flows. According to one exemplary embodiment of the present disclosure, the temperature of the substrate W may be controlled by setting the heating member 226 to a high temperature (e.g., 40° C.) while the process is performed.

The ring assembly 240 may be arranged in an edge area of the substrate support unit 200. The ring assembly 240 has a ring shape and may be arranged along the periphery of the electrostatic chuck 220. The ring assembly 240 may have a focus ring 242 and an insulating ring 244. The focus ring 242 is provided to surround the electrostatic chuck 220 and is capable of focusing plasma onto the substrate W. The insulating ring 244 may be provided to surround the focus ring 242. Optionally, the ring assembly 240 may include an edge ring (not shown) that is provided in close contact with the periphery of the focus ring 242 to prevent the side of the electrostatic chuck 220 from being damaged by plasma. The focus ring 242 may be provided with a silicon material, and the insulating ring 244 may be provided with a quartz material. Unlike the above description, the structure of the ring assembly 240 may be changed in various ways.

The substrate support unit 200 may include a driving unit 260. The driving unit 260 may raise and lower the substrate support unit 200 according to the process. The driving unit 260 may use a hydraulic cylinder, a pneumatic cylinder, etc., but is not limited thereto.

Unlike what is shown above, the substrate support unit 200 may be a metal stage rather than an electrostatic chuck. The metal stage may support the substrate W and may not include a vacuum hole or chucking electrode for fixing the substrate W. The metal stage may be raised and lowered so that a gap with a shower head 500 described later may be adjusted. The surface of the metal stage (the entire surface exposed to an etchant) may be coated with a lower region coating layer 570 described later. A heating member may be embedded in the metal stage, and the temperature of the substrate W may be controlled by setting the heating member to a high temperature (e.g., 40° C.).

The upper electrode module 300, the ion blocker 400, and the shower head 500 may be arranged above the substrate support unit 200.

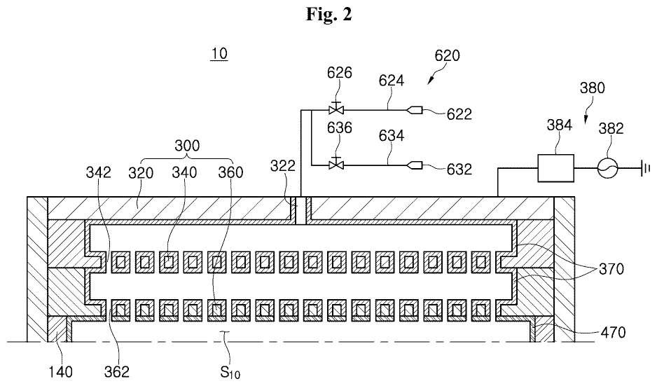

FIG. 2 is a view illustrating an upper electrode module according to one exemplary embodiment of the present disclosure.

Referring to FIG. 2, in order to vary a ratio depending on a region to which the gas supplied from the gas supply unit 600 described later is supplied, the upper electrode module 300 may include a first electrode 320, a second electrode 340, and a plate 360.

The first electrode 320 in a disc shape may be arranged at an uppermost part of the chamber 100. The first electrode 320 may be manufactured by using metal as a material, and a gas inlet 322 may be formed to deliver gas supplied from the gas supply unit 600 described later into the chamber 100. According to one exemplary embodiment of the present disclosure, only one gas inlet 322 formed in the first electrode 320 is illustrated, but this is not limited thereto and a plurality of gas inlets may be formed therein.

The second electrode 340 is arranged below the first electrode 320 and may have a disc shape. The second electrode 340 may be manufactured by using metal as a material, and may include a plurality of second electrode holes 342 to transfer gas supplied through the first electrode 320 into the chamber 100. The second electrode hole 342 may be radially arranged on the entire surface of the second electrode 340. The gas supplied from the gas inlet 322 may be evenly distributed in a space between the second electrode 340 and the first electrode 320.

The plate 360 is arranged below the second electrode 340 and may be provided to deliver gas supplied from the gas supply unit 600 described later to an upper region S10. The plate 360 may be manufactured in a disc shape by using metal as a material. A plurality of supply holes 362 may be formed in the plate 360 in order to supply the gas to the upper region S10, and the plurality of supply holes 362 may be arranged radially on the entire surface of the plate 360. The gas supplied from the plurality of second electrode holes 342 may be evenly distributed in the space between the plate 360 and the second electrode 340. Unlike what is illustrated above, the second electrode 340 may be omitted, and in this case, the gas supplied from the gas inlet 322 may also be evenly distributed in the space between the first electrode 320 and the plate 360. The number of electrodes or plates may be appropriately selected in order to evenly distribute the gas in the space described above.

Referring back to FIG. 1, a first insulating ring 140 may be provided below the upper electrode module 300. The first insulating ring 140 may have a ring shape and be formed of an insulator.

The ion blocker 400 is arranged at a lower part of the first insulating ring 140 and above the shower head 500, and may be installed facing the bottom surface of the chamber 100. The ion blocker 400 may divide the processing space inside the chamber 100 into the upper region S10 and a lower region S20. The ion blocker 400 may be manufactured by using silicon as a material, and may also be manufactured by using metal as a material. The ion blocker 400 may be provided in a plate shape, and for example, may have a disc shape. A plurality of through holes 400a may be formed in the ion blocker 400. The upper surface of the ion blocker 400 may face the lower surface of the plate 360.

A second insulating ring 160 may be provided below the ion blocker 400. The second insulating ring 160 may have a ring shape and may be formed of an insulator. A ring heating member 162 for heating a first region S22 of the lower region S20 may be provided inside the second insulating ring 160. For example, the ring heating member 162 may be a heating coil. According to one exemplary embodiment of the present disclosure, by heating the second insulating ring 160 using the ring heating member 162, particles remaining inside the first region S22 may be removed.

The shower head 500 is arranged below the ion blocker 400 and may be installed facing the substrate support unit 200. The shower head 500 may divide the lower region S20 into the first region S22 and a second region S24. The shower head 500 may be manufactured by using silicone as a material, and may also be manufactured by using metal as a material. The shower head 500 may be provided in a plate shape, and for example, may have a disc shape. The shower head 500 may be formed with a plurality of gas injection holes 500a in order to supply gas.

A high-frequency power module 380 may be connected to the upper electrode module 300, and the high-frequency power module 380 may apply RF power to the upper electrode module 300 to excite gas supplied to the chamber 100, and may generate plasma inside the chamber 100. According to one exemplary embodiment of the present disclosure, such plasma may be generated by using a Capacitively Coupled Plasma (CCP) source, but the present disclosure is not limited thereto. For example, plasma may be generated by using an Inductively Coupled Plasma (ICP) source.

The high-frequency power module 380 may include a high-frequency power supply 382 and an impedance matcher 384. The ion blocker 400 and shower head 500 may be grounded.

According to one exemplary embodiment of the present disclosure, the space divided by the plate 360 of the upper electrode module 300, the first insulating ring 140, and the ion blocker 400 may be the upper region S10. The upper region S10 may be a region where plasma is formed by receiving gas supplied from the first gas supply unit 620 of the gas supply unit 600 described later. The upper region S10 may be referred to as a plasma region. In the upper region S10, plasma effluents such as radicals, ions, or electrons are formed. The ion blocker 400 filters out the ions and the remaining plasma effluents may be transferred to the lower region S20 through the ion blocker 400.

In addition, the space divided by the ion blocker 400, the second insulating ring 160, and the shower head 500 may be the first region S22 of the lower region S20, and may be a region through which radicals of the plasma formed in the upper region S10 pass. The first region S22 may be referred to as an ion filtering region. The second region S24 of the lower region S20 may be a region that receives gas supplied from the second gas supply unit 640 of the gas supply unit 600 described later and mixes this gas with the radicals in the plasma formed in the upper region S10, so as to generate an etchant. In addition, this region may be a substrate processing space where a substrate processing process is performed by using the generated etchant.

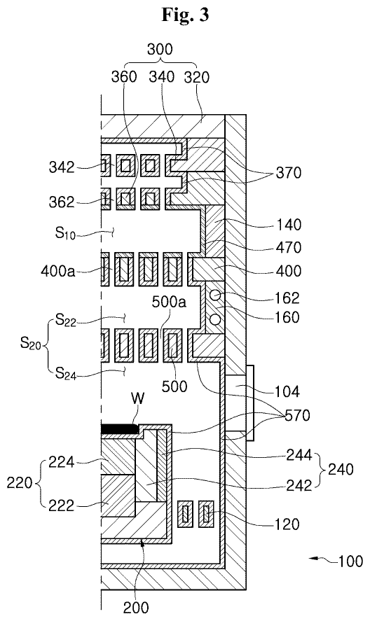

FIG. 3 is an enlarged view illustrating coating layers formed in the substrate processing apparatus according to one exemplary embodiment of the present disclosure.

According to one exemplary embodiment of the present disclosure, an upper electrode module coating layer 370 may be formed on the upper electrode module 300. The upper electrode module coating layer 370 may be formed on each of the first electrode 320, the second electrode 340, and the plate 360. More specifically, an upper electrode module coating layer 370 may be formed on at least a part or all of surfaces exposed to the gas supplied from the first gas supply unit 620, the surfaces including: a lower surface of the first electrode 320, an inner side surface of the gas inlet 322, upper/lower/inner side surfaces of the second electrode 340, inner side surfaces of a plurality of second electrode holes 342, upper/inner side surfaces of the plate 360, and inner side surfaces of a plurality of supply holes 362. The upper electrode module coating layer 370 may include nickel (Ni). The upper electrode module coating layer 370 may further include phosphorus (P). According to one exemplary embodiment of the present disclosure, by forming a nickel coating layer (e.g., the upper electrode module coating layer 370) on the upper electrode module 300, the amount of F radicals may be scavenged, i.e., captured. In this way, the F radicals may be captured in the nickel coating layer 370 and the amount of F radicals supplied inside the chamber 100 may be maintained constant, so the amount of polysilicon etched may be maintained constant even when the number of process cycles increases.

An upper region coating layer 470 may be formed in the upper region S10. The upper region coating layer 470 may be formed on each of a lower surface of the plate 360, an inner side surface of the first insulating ring 140, and an upper surface of the ion blocker 400. More specifically, an upper region coating layer 470 may be formed on at least a part or all of surfaces of the plate 360, the first insulating ring 140, and the ion blocker 400, which are exposed to plasma generated in the upper region S10. The upper region coating layer 470 may be a ceramic coating (e.g., yttrium oxide (Y2O3)) with excellent plasma resistance properties. In another example, the upper region coating layer 470 may also be an anodized aluminum coating.

A lower region coating layer 570 may be formed in the lower region S20. Specifically, a lower region coating layer 570 may be formed on at least a part or all of surfaces including: a lower surface of the ion blocker 400, an inner side surface of the second insulating ring 160, upper/lower surfaces of the shower head 500, inner side surfaces of a plurality of gas injection holes 500a, an inner wall of the chamber 100, upper and lower surfaces of the baffle unit 120, an inner side surface of a hole of the baffle unit 120, an inner wall of the chamber 100 from the baffle unit 120 to the exhaust port 102, side and lower surfaces of the substrate support unit 200, and upper and side surfaces of the substrate support unit 200. The lower region coating layer 570 may include nickel (Ni). The lower region coating layer 570 may further include phosphorus (P). In this way, by forming the lower region coating layer 570, the lower region coating layer 570 may capture unreacted F radicals or may maximally reduce particles inside the chamber 100 generated by the process gas.

Referring back to FIG. 1, the gas supply unit 600 may supply gas required for processing a substrate W and for others to the chamber 100. The gas supply unit 600 according to one exemplary embodiment of the present disclosure may include a first gas supply unit 620 and a second gas supply unit 640.

The gas supply units 620 and 640 may include respective gas supply sources 622 and 642, respective gas supply lines 624 and 644, and respective gas injection nozzles. The gas supply lines 624 and 644 may connect the respective gas supply sources 622 and 642 to the respective gas injection nozzles. Valves 626 and 646 may be respectively installed in the gas supply lines 624 and 644 in order to open and close their passages or to control the flow rates of the fluid flowing through the passages.

In order to supply gas to the internal space of the chamber 100, the first gas supply unit 620 may include the gas supply source 622 and the gas supply line 624. The gas valve 626 for controlling the flow rate of the supplied gas may be provided in the gas supply line 624. Specifically, the first gas supply unit 620 may supply the gas to the upper region S10. The gas supplied from the first gas supply unit 620 according to one exemplary embodiment of the present disclosure is a fluorine-containing gas, and may be any one of NF3, SF6, SiF4, and XeF2.

In addition, the first gas supply unit 620 may further include a gas supply source 632, a gas supply line 634, and a gas valve 636, which are for supplying an inert gas together with the fluorine-containing gas. The inert gas may be any one of Ar, He, Xe and N2.

In order to supply gas to the internal space of the chamber 100, the second gas supply unit 640 may include the gas supply source 642 and the gas supply line 644. The gas valve 646 for controlling the flow rate of the supplied gas may be provided in the gas supply line 644. Specifically, the second gas supply unit 640 is connected to the shower head 500 and may supply gas to the second region S24 of the lower region S20. The gas supplied from the second gas supply unit 640 according to one exemplary embodiment of the present disclosure is a hydrogen-containing gas, and may be any one of NH3, CH4, and C4H8.

In addition, the second gas supply unit 640 may further include a gas supply source 652, a gas supply line 654, and a gas valve 656, which are for supplying an inert gas together with the hydrogen-containing gas. The inert gas may be any one of Ar, He, Xe and N2.

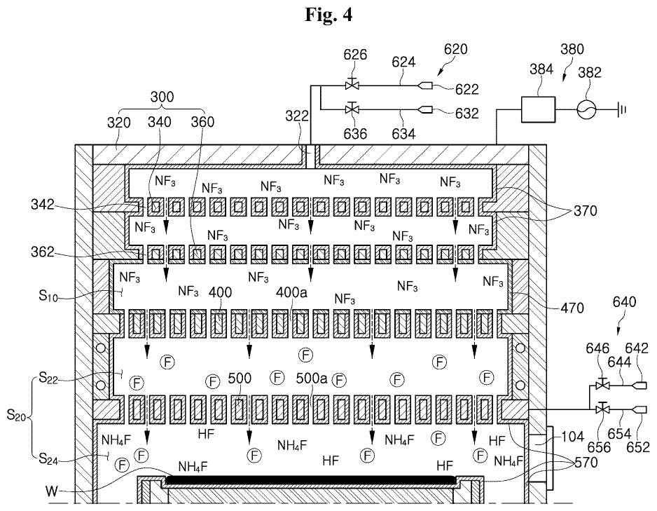

FIG. 4 is a view illustrating gas flow in the upper region and the lower region according to one exemplary embodiment of the present disclosure.

Referring to FIG. 4, a fluorine-containing gas is supplied to the upper region S10 via the upper electrode module 300 by using the first gas supply unit 620, and the supplied gas may transition into a plasma state by the high-frequency power module 380 of the upper electrode module 300. Specifically, the fluorine-containing gas may be decomposed into ions, electrons, and F radicals as the gas transitions to the plasma state. The ions and electrons are absorbed by the ion blocker 400, and the F radicals may move to the first region S22 of the lower region S20. The F radicals may pass through the first region S22 and be supplied to the second region S24. The hydrogen-containing gas supplied to the second region S24 from the second gas supply unit 640 connected to the shower head 500 may react with the radicals, having passed through the ion blocker 400 and the shower head 500, in the plasma generated from the first gas supply unit 620, so as to generate an etchant. The hydrogen-containing gas supplied to the second region S24 may react with the F radicals that are generated in the upper region S10, passed through the first region S22 of the lower region S20, and supplied to the second region S24, so as to generate HF or NH4F (F*+NH3→NH4F or HF). HF or NH4F may react with SiO2 on the surface of the substrate W, so as to produce (NH4)2SiF6 or H2O (NH4F4+4HF+SiO2→(NH4)2SiF6+2H2O). (NH4)2SiF6 may also be heated by the substrate support unit 200 and removed through the exhaust port 102 ((NH4)2SiF6→SiF4+2NH3+2HF). According to the above-described operations, the substrate processing apparatus 10 may etch the silicon oxide film (SiO2) of the substrate W.

Referring back to FIG. 1, the control unit 700 may comprehensively control the operation of the substrate processing apparatus 10 configured as described above. For example, the control unit 700 may be a computer and be provided with an auxiliary memory device, etc. The CPU operates on the basis of a program stored in a ROM or the auxiliary memory device or on the basis of process conditions, and may control the operation of the entire substrate processing apparatus 10. In addition, a computer-readable program required for the control may also be stored in a storage medium. As an example, the storage medium may be a flexible disc, a compact disc (CD), a CD-ROM, a hard disc, a flash memory, a DVD, or the like. The control unit 700 may be provided inside or outside the substrate processing apparatus 10. In a case where the control unit 700 is provided externally, the control unit 700 may control the substrate processing apparatus 10 by a wired or wireless communication means.

While performing the process on the substrate W, the control unit 700 according to one exemplary embodiment of the present disclosure may control the heating member 226 to set the temperature of the substrate support unit 200 to 40° C. or higher and may control the ring heating member 162 to set the temperature of the inner wall of the chamber 100 to 60° C. or higher. In addition, the control unit 700 may control the supply amount of fluorine-containing gas and hydrogen-containing gas, which are supplied to the upper region S10 and the second region S24 of the lower region S20.

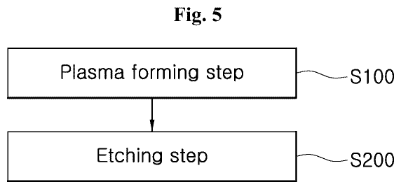

FIG. 5 is a flowchart illustrating a substrate processing method according to one exemplary embodiment of the present disclosure. Since the substrate processing method of the present disclosure uses the substrate processing apparatus in FIG. 1, this method will be described with reference to both FIG. 1 and FIG. 5.

Referring to FIGS. 1 and 5, in a method of etching a substrate, the method may include: a plasma forming step S100 of forming plasma by supplying a fluorine-containing gas from a first gas supply unit to an upper region S10; and an etching step S200 of supplying a hydrogen-containing gas to a second region S24 of a lower region S20, mixing radicals in the plasma generated in the plasma forming step with the hydrogen-containing gas supplied to the second region S20 so as to form an etchant, and etching the substrate by using the generated etchant. The plasma forming step S100 and the etching step S200 are considered as one cycle, and by repeating the process at least once, the substrate W may be etched to a desired thickness. Such a substrate processing method may be performed at a temperature of 40° C. or higher.

The plasma forming step S100 is the step of forming plasma by supplying the gas from the first gas supply unit 620 to the upper region S10. A fluorine-containing gas may be supplied to the upper region S10 from the first gas supply unit 620, and the supplied fluorine-containing gas may be converted into the plasma. The fluorine-containing gas supplied from the first gas supply unit 620 to the upper region S10 may be any one of NF3, SF6, SiF4, and XeF2. The gas supplied to the upper region S10 from the first gas supply unit 620 according to one exemplary embodiment of the present disclosure may be NF3, but is not limited thereto. The NF3 gas supplied to the upper region S10 may transition into a plasma state. When transitioning to the plasma state, the NF3 gas may be decomposed into ions, electrons, and radicals. For example, the NF3 of the present disclosure may transition into a plasma state and be decomposed into F radicals and NF2 ions. The radical components generated by passing through an ion blocker 400 moves to the lower region S20, and the ions and electrons may be absorbed by the ion blocker 400.

The etching step S200 is the step of generating an etchant and etching the substrate W by using the generated etchant. A hydrogen-containing gas is supplied from the second gas supply unit 640 to the second region S24 of the lower region S20, and the supplied hydrogen-containing gas is mixed with the radicals that is supplied to the second region S24 through the ion blocker 400 and the first region S22 of the lower region S20 in the plasma forming step S100, thereby generating the etchant. At the same time, the substrate W may be etched by using the generated etchant. The hydrogen-containing gas supplied from the second gas supply unit 640 to the second area S24 may be any one of NH3, CH4, and C4H8. According to one exemplary embodiment of the present disclosure, the gas supplied to the second region S24 from the second gas supply unit 640 is NH3, and the etchant generated by using the gas is NH4F and HF, and unmixed F radicals may be supplied directly to the substrate W. A surface layer of the silicon oxide film may be etched while the silicon oxide film reacts with the generated etchant and generates volatile etching byproducts. In case of polysilicon, this polysilicon may be etched by the unmixed F radicals.

The amount of polysilicon etched is confirmed by using the substrate processing apparatus and substrate processing method of the present disclosure.

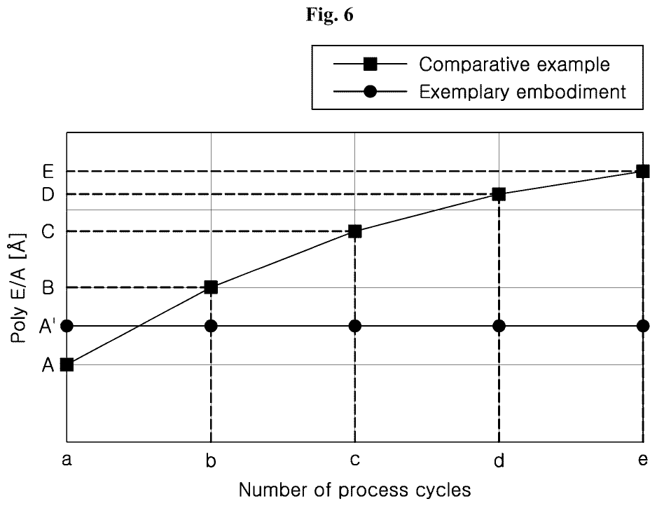

FIG. 6 is a graph illustrating the amounts of polysilicon etched depending on the number of process cycles. In a case of a, b, c, d, and e shown on the X-axis in FIG. 6, there exists a relationship of a<b<c<d<e, meaning that a is the smallest and e is the largest. In addition, in a case of A, B, C, D, and E shown on the Y-axis, there exists a relationship of A<B<C<D<E, meaning that A is the smallest and E is the largest. In a case of A′, this A′ exists between A and B, meaning that there exists a relationship of A <A′<B.

In the exemplary embodiment, FIG. 6 is a graph illustrating the amounts of polysilicon etched depending on the number of substrate process cycles when a substrate W is processed by the substrate processing apparatus 10 described above in FIGS. 1 to 4. A path from the first gas supply unit 620 to the substrate W may correspond to components including: an upper electrode module 300 having an upper electrode module coating layer 370 including nickel (Ni); an upper region S10 having an upper region coating layer 470 including a ceramic coating; and a lower region S20 having a lower region coating layer 570 including nickel (Ni).

In FIG. 6, unlike the exemplary embodiment, a comparative example illustrates a case where the upper electrode module 300 is anodized, rather than being coated with nickel (Ni). In the comparative example, the path from the first gas supply unit 620 to the substrate W may correspond to components including: an upper electrode module anodized; an upper region S10 having an upper region coating layer 470 including a ceramic coating; and a lower region S20 having a lower region coating layer 570 including nickel (Ni). The difference between the comparative example and the present exemplary embodiment is whether a region encompassing from the gas inlet 322 to the upper region S10 where plasma is generated is coated with nickel (Ni) or is anodized.

Referring to FIG. 6, in a case where a polysilicon substrate is etched by using a conventional upper electrode module anodized, it may be seen that as the number of process cycles increases, the amount of polysilicon etched also increases. Specifically, in the case of the upper electrode module anodized, as the number of process cycles increases, the reaction between Al2O3 and F radicals decreases, so the amount of F radicals increases compared to that in the beginning of the etching process, whereby the amount of polysilicon etched also increases.

In a case where a polysilicon substrate is etched by using the nickel-coated upper electrode module 300 of the present disclosure, it may be seen that the amount of polysilicon etched is constant even when the number of process cycles increases. Specifically, it may be seen that the amount of polysilicon etched is maintained constant even when the number of process cycles increases because the constant amount of F radicals is captured by the nickel-coated upper electrode module. In particular, depending on the process conditions, the F radicals in the upper region S10 may flow back to the upper electrode module 300 rather than to the lower region S20. Accordingly, unlike the comparative example in which only the lower region S20 is nickel-coated relative to the upper region S10 where plasma is generated, in the exemplary embodiment in which nickel-coating is processed up to the upper electrode module 300 located above the upper region S10 where plasma is generated, the amount of polysilicon etched may be maintained more consistently.

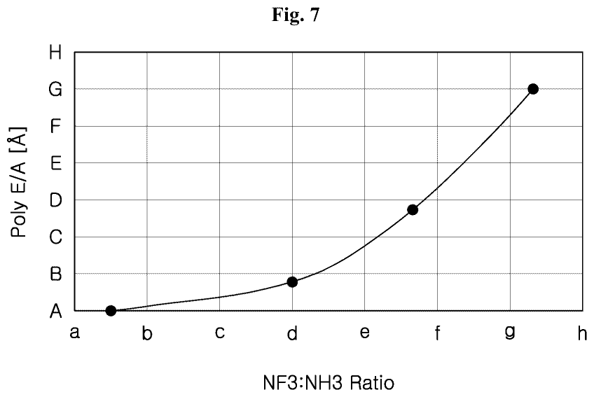

FIG. 7 is a graph illustrating the amounts of polysilicon etched depending on the supply ratio of fluorine-containing gas and hydrogen-containing gas in the substrate processing apparatus including the nickel-coated upper electrode module according to one exemplary embodiment of the present disclosure.

Referring to FIG. 7, this is a graph illustrating the amounts of polysilicon etched depending on change in the supply ratio of NF3 gas while constantly maintaining the total amount of gas supplied into a chamber through a gas supply unit. In a case of a, b, c, d, e, f, g, and h shown on the X-axis in FIG. 7, there exists a relationship of a<b<c<d<e<f<g<h. This means that a has the smallest supply ratio of NF3 gas, and h has the largest supply ratio of NF3 gas. In addition, in a case of A, B, C, D, E, F, G, and H shown on the Y-axis, there exists a relationship of A<B<C<D<E<F<G<H, meaning that A is the smallest and H is the largest.

As shown in the above results, as the supply ratio of NF3 gas increases, the amount of polysilicon etched increases. This means that the amount of polysilicon etched may be accurately controlled by the nickel-coated upper electrode module even when the number of process cycles is increased. If a nickel coating layer is not formed on an upper electrode module, it is difficult to control the amount of polysilicon etched because the amount of polysilicon etched continues to change while the process is performed. Therefore, by forming the nickel coating layer on the upper electrode module, the selectivity between the polysilicon and the silicon oxide film is controllable even when the number of process cycles increases, thereby improving the process yield.

The above descriptions are merely examples of the technical idea of the present disclosure, and those skilled in the art will appreciate that various modifications and variations can be made without departing from the essential characteristics of the present invention. Therefore, the embodiments described in the present disclosure are not intended to limit the technical idea of the present disclosure but to describe the present disclosure, and the technical idea of the present disclosure is not limited by these embodiments. The scope of protection of the present disclosure should be interpreted by the following claims, and all technical ideas within the scope equivalent thereto should be construed as being included in the scope of the present disclosure.

What is claimed is:

1. A substrate processing apparatus, comprising:
a chamber having a processing space therein;
a substrate support unit arranged in the processing space and for supporting a substrate;
an ion blocker arranged above the substrate support unit and for dividing the processing space into an upper region where plasma is generated and a lower region;
a gas supply unit for supplying a fluorine-containing gas to the upper region;
an upper electrode module provided with a coating layer and arranged above the ion blocker and for supplying the fluorine-containing gas to the upper region; and
a high-frequency power module for applying electric power to the upper electrode module to generate the plasma in the upper region,
wherein the coating layer for capturing fluorine radicals of the plasma is formed on at least a part of a surface of the upper electrode module.

2. The substrate processing apparatus of claim 1,
wherein the coating layer comprises nickel.

3. The substrate processing apparatus of claim 2,
wherein the upper electrode module comprises:
a first electrode;
a second electrode arranged below the first electrode; and
a plate arranged below the second electrode.

4. The substrate processing apparatus of claim 1,
wherein an upper region coating layer is formed in the upper region, and
the upper region coating layer comprises Y₂O₃.

5. The substrate processing apparatus of claim 1,
wherein a lower region coating layer is formed in the lower region, and
the lower region coating layer comprises nickel.

6. The substrate processing apparatus of claim 1,
wherein the gas supply unit comprises:
a first gas supply unit for supplying the fluorine-containing gas to the upper region; and
a second gas supply unit for supplying a hydrogen-containing gas to the lower region.

7. The substrate processing apparatus of claim 6,
wherein the fluorine-containing gas is any one of NF3, SF6, SiF4, and XeF2.

8. The substrate processing apparatus of claim 6,
wherein the hydrogen-containing gas is any one of NH3, CH4, and C4H8.

9. The substrate processing apparatus of claim 6, further comprising:
a shower head arranged below the ion blocker and for dividing the lower region into a first region and a second region,
wherein the first region of the lower region is a region where the fluorine radicals are transferred by the ion blocker in the plasma, and
the second region of the lower region is a region where the fluorine radicals passing through the first region are mixed with the hydrogen-containing gas so as to form an etchant and a substrate processing process is performed.

10. A substrate processing apparatus, comprising:
a chamber having a processing space therein;
a substrate support unit arranged in the processing space and for supporting a substrate;
an ion blocker arranged above the substrate support unit and for dividing the processing space into an upper region and a lower region;
a shower head arranged below the ion blocker and dividing the lower region into a first region and a second region;
a gas supply unit for supplying a fluorine-containing gas to the upper region;
an upper electrode module provided with a coating layer and arranged above the ion blocker and for supplying the fluorine-containing gas to the upper region;
a high-frequency power module for applying electric power to the upper electrode module to generate plasma in the upper region; and
a control unit for controlling the gas supply unit and the high-frequency power module,
wherein the upper electrode module comprises:
a first electrode;
a second electrode arranged below the first electrode; and
a plate arranged below the second electrode,
wherein the coating layer is formed on a surface of the upper electrode module, and
wherein the coating layer comprises nickel.

11. The substrate processing apparatus of claim 10,
wherein an upper region coating layer is formed in the upper region, and
the upper region coating layer comprises Y₂O₃.

12. The substrate processing apparatus of claim 10,
wherein a lower region coating layer is formed in the lower region, and
the lower region coating layer comprises the nickel.

13. The substrate processing apparatus of claim 10, wherein the gas supply unit comprises:
a first gas supply unit for supplying the fluorine-containing gas to the upper region; and
a second gas supply unit for supplying a hydrogen-containing gas to the lower region.

14. The substrate processing apparatus of claim 13,
wherein the fluorine-containing gas is any one of NF3, SF6, SiF4, and XeF2, and
the hydrogen-containing gas is any one of NH3, CH4, and C4H8.

15. A method of processing a substrate in a substrate processing apparatus comprising a chamber having a processing space therein, a substrate support unit arranged in the processing space and configured to support the substrate, an ion blocker arranged above the substrate support unit and configured to divide the processing space into an upper region and a lower region, an upper electrode module arranged above the ion blocker and configured to supply a fluorine-containing gas to the upper region and have at least a part thereof comprising a coating layer comprising nickel, a high-frequency power module configured to apply electric power to the upper electrode module to generate plasma in the upper region, the method comprising:
a plasma forming step of forming the plasma by supplying the fluorine-containing gas to the upper region; and
an etching step of supplying a hydrogen-containing gas to the lower region, mixing radicals of the plasma generated in the plasma forming step with the hydrogen-containing gas supplied to the lower region so as to form an etchant, and etching the substrate by using the etchant.

16. The method of claim 15,
wherein a cycle comprising the plasma forming step and the etching step is repeated at least once.

17. The method of claim 15,
wherein the substrate comprises polysilicon and a silicon oxide film.

18. The method of claim 15,
wherein the radicals mixed with the hydrogen-containing gas in order to form the etchant in the etching step are fluorine radicals.

19. The method of claim 15,
wherein the etchant formed in the etching step is HF or NH4F.

20. The method of claim 15,
wherein the upper electrode module comprises:
a first electrode;
a second electrode arranged below the first electrode; and
a plate arranged below the second electrode and formed with a plurality of holes, and
the coating layer is formed on an inner side surface of the plurality of holes and on an upper surface of the plate.
